(19) United States
(12) Patent Application Publication
(10) Pub. No.: US 2008/0315300 A1
(43) Pub. Date: Dec. 25, 2008

(54) Semiconductor device and method for manufacturing semiconductor device

(75) Inventor: Toshiyuki Higashino, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/213,197

(22) Filed: Jun. 16, 2008

(30) Foreign Application Priority Data
Jun. 19, 2007 (JP) P2007-161240

(51) Int. Cl. H01L 29/78; H01L 21/336

(52) U.S. Cl. 257/329; 438/268; 257/E21.41; 257/E29.262

(57) ABSTRACT

A semiconductor device includes: a semiconductor substrate having a substrate surface; a spiral body constituted by a linear semiconductor layer on which a body region including a channel region, a first source/drain region disposed on the body region, and a second source/drain region disposed under the body region or in the semiconductor substrate around the linear semiconductor layer are formed, the linear semiconductor layer being formed on the substrate surface substantially in a spiral form viewed from the substrate surface in a plan view, formed substantially in a protrudent form in a cross-sectional view, and having a pair of sidewall portions; a gate insulating film formed on at least the pair of sidewall portions constituting the linear semiconductor layer; and a gate electrode that is adjacent to the pair of sidewall portions via the gate insulating film.

### BACKGROUND OF THE INVENTION

1. Field of the Invention

The present invention relates to a semiconductor device and a method for manufacturing a semiconductor device.

Priority is claimed on Japanese Patent Application No. 2007-161240, filed Jun. 19, 2007, the content of which is incorporated herein by reference.

2. Description of the Related Art

In recent years, with the rapid development of mobile information communication terminals as represented by cellular phones, the requirements of components mounted thereon, i.e., semiconductor integrated circuits, such as low power consumption and high integration density have become strict.

As an example of a conventional semiconductor device, those disclosed in Japanese Unexamined Patent Application, First Publication No. H05-007003, Japanese Unexamined Patent Application, First Publication No. 2004-039806, and Japanese Unexamined Patent Application, First Publication No. 2005-236290 can be referred to.

For realization of a higher integration density of a semiconductor integrated circuit, it is preferable to replace a conventional planar type MOS transistor with a new transistor having a novel structure.

Referring to FIG. 14, a sectional structure of a SOI-CMOS transistor is illustrated as an example of a transistor having a novel structure.

The SOI-CMOS transistor 101 employs a semiconductor substrate formed from a so-called SOI wafer instead of using a semiconductor substrate formed from a general silicon wafer.

As shown in FIG. 14, the semiconductor substrate 102 formed from the SOI wafer is constructed so that a wafer body 102a formed from single-crystalline silicon, a buried oxide film 102b, and a silicon layer 102c are sequentially laminated therein.

The SOI-CMOS transistor 101 is generally composed of a source region 103 and a drain region 104 that are formed on the silicon layer 102c, a body region 105 that is disposed between the source region 103 and the drain region 104, a gate insulating film 106 formed from silicon oxide and formed on the body region 105, and a gate electrode 107 formed from polysilicon and formed on the gate insulating film 106.

The source region 103 and the drain region 104 are impurity diffusion regions which are formed by ion-implanting N-type impurities in the silicon layer 102c, while the body region 105 is an impurity diffusion region which is formed by ion-implanting P-type impurities in the silicon layer 102c.

In addition, sidewalls 108 formed from silicon nitride are formed at both sides of the gate electrode 107.

Moreover, an interlayer insulating film 109 formed from silicon oxide is laminated so as to cover the gate electrode 107 and the silicon layer 102c.

Furthermore, in the interlayer insulating film 109, contact plugs 110a, 110b, and 110c are formed so as to be connected to the gate electrode 107, the source region 103, and the drain region 104, respectively.

According to the SOI-CMOS transistor described above, the silicon layer 102c having impurity diffusion regions such as the body region 105 is electrically isolated from the wafer body 102a by the buried oxide film 102b. Therefore, it is possible to provide advantages such as parasitic capacitance reduction, latch-up free, junction leakage reduction, or short channel effect suppression.

However, the SOI wafers are more expensive than the conventional single-crystalline silicon wafers, and therefore, there is a desire to provide a transistor having characteristics equivalent to the SOI-CMOS transistor by using the conventional single-crystalline silicon wafers.

In addition, the SOI wafers have a drawback in that the thermal conductivity of the buried oxide film differs greatly from that of the silicon layer, which causes the self-heating effect.

Therefore, it is preferable to provide a transistor capable of effectively radiating the heat generated therein in a manner similar to a general substrate.

In addition, it is preferable to have a structure that can utilize the design assets of the conventional transistor and that can be applied to a floating body type transistor that is used in memory cells of a capacitor-less DRAM.

This structure can separate the substrate region from the body region; therefore, a structure capable of storing a large amount of impact-ionized holes can be provided.

However, when the transistor is manufactured with such a structure, it is difficult to introduce dopants using the conventional ion implantation method.

According to another trend, novel materials such as a high-K gate insulating film or a metal gate electrode are developed for the improvement of the conventional planar type MOS transistor.

However, as the requirements for the higher integration density become stricter, the gate length will decrease year after year, and it is thus thought that it will ultimately reach the limit within 20 years in future.

It is therefore preferable to develop a mass production technology that can maintain or improve the ON current while faithfully maintaining the pace of Moore's law.

For this reason, a structure is desired which enables stricter control of dopant distribution and improved gate controllability.

In order for this to work, it is necessary that a source region, a drain region, and a body region are formed so that the dopant distribution is controlled as precisely as possible on the order of nano-meters, while ensuring that the regions are separated from each other.

However, when the channel is formed in the body region, it is difficult to practically control the current in the small gate region and thus the short channel effect occurs.

For this reason, in order to form the channel over the entire body region of the silicon layer, it is necessary to ensure a large gate region and then control the current to thereby suppress the short channel effect.

However, the planar type transistor with an all-around gate requires a complex manufacturing process.

Meanwhile, as a vertical transistor with an all-around gate that is easy to manufacture, an SGT (surround gate transistor) is developed having a structure in which a gate insulating film and a gate electrode are formed so as to surround a silicon pillar including a source/drain region and a channel region.

However, in order to increase the ON current, the silicon pillar has to have a large diameter in order to ensure a large channel region.

For this reason, the rate of increase in the ON current per unit area is small, and as a result, the silicon layer becomes thicker, which will change the threshold voltage.

Meanwhile, as another example of the vertical transistor, a double-gate transistor is developed.

However, in the vertical double-gate transistor, in order to increase the ON current, it is necessary to increase the channel width. In order for this to work, it is necessary for the gate electrodes to be disposed at both sides of the silicon layer that forms a channel. As a result, the area per unit wafer of a transistor increases. In addition, a so-called fin-type transistor (FinFET) is known. However, in the FinFET, in order to increase the ON current, it is necessary that the silicon layer that forms a channel is thick or large in the horizontal direction.

For this reason, the FinFET is disadvantageous in terms of integration with a conventional planar transistor, usability as a substitute, and area efficiency.

In addition, in order to manufacture a transistor having an extremely short channel length, the conventional ion implantation process needs to be used. Therefore, it is disadvantageous for realization of an extremely short channel length.

Moreover, since the transistor is shaped to extend in a direction perpendicular to or parallel to the substrate, the transistor has an unbalanced shape that does not exhibit the inherent characteristics of the FinFET. Therefore, there is a problem in that the manufacturing the transistor is practically impossible.

### SUMMARY OF THE INVENTION

In light of the above circumstances, an object of the invention is to provide a semiconductor device and a method for manufacturing a semiconductor device in which it is possible to realize an extremely short channel length and to increase the ON current without changing the threshold value.

In order to solve the above problems, the invention provides the following constitution.

The semiconductor device of a first aspect of the invention includes: a semiconductor substrate having a substrate surface; a spiral body constituted by a linear semiconductor layer on which a body region including a channel region, a first source/drain region disposed on the body region, and a second source/drain region disposed under the body region or in the semiconductor substrate around the linear semiconductor layer are formed, the linear semiconductor layer being formed on the substrate surface substantially in a spiral form viewed from the substrate surface in a plan view, formed substantially in a protrudent form in a cross-sectional view, and having a pair of sidewall portions; a gate insulating film formed on at least the pair of sidewall portions constituting the linear semiconductor layer; and a gate electrode that is adjacent to the pair of sidewall portions via the gate insulating film. In the semiconductor device, the gate insulating film is disposed between the body region and the gate electrode.

It is preferable that, in the semiconductor device of the first aspect of the invention, a thickness of the linear semiconductor layer, a width of the linear semiconductor layer, and a thickness of the gate insulating film be constant over the spiral body from a peripheral spiral to a central spiral.

It is preferable that the semiconductor device of the first aspect of the invention further include: an interlayer insulating film formed on the semiconductor substrate, covering the spiral body, the gate insulating film, and the gate electrode; a lead-out electrode used for source/drain; a first contact plug that is connected with the first source/drain region and provided to the interlayer insulating film; a second contact plug that is connected with the second source/drain region and provided to the interlayer insulating film; and a gate contact plug that is connected with the gate electrode and provided to the interlayer insulating film. In the semiconductor device, an end at a peripheral side of the gate electrode is directly connected with the gate contact plug, the first source/drain region is directly connected with the first contact plug, and the second source/drain region is directly connected with the second contact plug via the lead-out electrode.

It is preferable that, in the semiconductor device of the first aspect of the invention, the second contact plug be disposed at a position symmetric to the gate contact plug with respect to a spiral center of the spiral body and the first contact plug be disposed above the spiral center.

It is preferable that, in the semiconductor device of the first aspect of the invention, the pair of sidewall portions constituting the linear semiconductor layer be formed a round surface.

The method for manufacturing a semiconductor device of a second aspect of the invention includes: providing a semiconductor substrate having a substrate surface; sequentially forming a first semiconductor film that becomes a second source/drain region, a second semiconductor film that becomes a body region including a channel region, and a third semiconductor film that becomes a first source/drain region, on the semiconductor substrate; patterning the third semiconductor film, the second semiconductor film, and a part of the first semiconductor film so as to form a linear semiconductor layer that is formed substantially in a protrudent form in a cross-sectional view and that has a pair of sidewall portions, so that the linear semiconductor layer is formed substantially in a spiral form viewed from the substrate surface in a plan view, and so that a spiral body constituted by the linear semiconductor layer is formed; forming a gate insulating film on at least the pair of sidewall portions of the linear semiconductor layer; and forming a gate electrode that is opposed to the pair of sidewall portions via the gate insulating film.

The method for manufacturing a semiconductor device of a third aspect of the invention includes: providing a semiconductor substrate having a substrate surface; patterning the substrate surface so as to form a linear semiconductor layer that is formed substantially in a protrudent form in a cross-sectional view and has a pair of sidewall portions, so that the linear semiconductor layer is formed substantially in a spiral form viewed from the substrate surface in a plan view; sequentially introducing impurities into the semiconductor substrate around the linear semiconductor layer and into the linear semiconductor layer so as to form a second source/drain region in the semiconductor substrate around the linear semiconductor layer and so as to form a body region including a channel region and a first source/drain region on the linear semiconductor layer; forming a gate insulating film so as to cover the linear semiconductor layer; and forming a gate electrode that is opposed to the pair of sidewall portions via the gate insulating film.

According to the above-described semiconductor device, since the linear semiconductor layer including the channel region is formed in a spiral form, the area of the channel region decreases, it is thereby possible to make the semiconductor device small in size and to realize a high integration LSI circuit.

In addition, by employing the spiral structure, it is easy to increase the length of the linear semiconductor layer. Therefore, it is possible to increase the area of the channel region opposed to the gate electrode and to thus increase the ON current.

Furthermore, since the gate electrode is formed so as to face to the pair of sidewall portions of the linear semiconductor layer, it is possible to suppress short channel effect. In addition, since the gate insulating film is disposed between the body region including the channel region and the gate electrode, it is possible to further suppress the short channel effect.

Furthermore, according to the above-described semiconductor device, since the thickness of the linear semiconductor layer, the width of the linear semiconductor layer, and the thickness of the gate insulating film are constant over the spiral body from the peripheral spiral to the central spiral, it is possible to conserve threshold voltage and to thus further increase the ON current.

Furthermore, according to the above-described semiconductor device, the gate electrode is directly connected with the gate contact plug, the first source/drain region is directly connected with the first contact plug, and the second source/drain region is directly connected with the second contact plug via the lead-out electrode. It is thereby possible to separate the position of the second contact plug from the first contact plug and the gate contact plug and to thus decrease the parasitic capacitance between the contact plugs.

Furthermore, since the spiral body having the channel region is covered with the interlayer insulating film, a perfect depletion type transistor can be constituted.

Furthermore, since the second contact plug is disposed at a position symmetric to the gate contact plug with respect to the spiral center of the spiral body, and since the first contact plug is disposed above the spiral center, it is possible to further decrease the parasitic capacitance between the contact plugs.

Furthermore, according to the above-described semiconductor device, the pair of sidewall portions of the linear semiconductor layer is formed of a round surface, it is possible to realize a structure that is not sensitive to an electric field.

Furthermore, according to the above-described semiconductor device, the pair of sidewall portions constituting the linear semiconductor layer is parallel with a crystal axis of a single-crystalline silicon constituting the semiconductor substrate. Also, an interface of the first source/drain region and the body region, an interface of the second source/drain region and the body region, and a crystal axis of a single-crystalline silicon constituting the semiconductor substrate are parallel with each other. It is thereby possible to further suppress the short channel effect.

Next, according to the above-described method for manufacturing the semiconductor device, since the first semiconductor film, the second semiconductor film, and the third semiconductor film, which become the second source/drain region, the body region including a channel region, and the first source/drain region, respectively, are sequentially formed, it is therefore possible to control the impurity concentration in each region in a simple manner. Accordingly, it is possible to simplify the design of the semiconductor device.

Furthermore, according to the above-described method for manufacturing the semiconductor device, the spiral body constituted by the linear semiconductor layer is formed, the gate insulating film is formed on the pair of sidewall portions of the linear semiconductor layer, and the gate electrode that faces the pair of sidewall portions via the gate insulating film is formed. Therefore, the area of the linear semiconductor layer including the channel region decreases, it is possible to manufacture a small semiconductor device and to realize a high integration LSI circuit. In addition, by employing the spiral structure, it is easy to increase the length of the linear semiconductor layer. Therefore, it is possible to increase the area of the channel region opposed to the gate electrode and to thus manufacture the semiconductor device having a large ON current.

Furthermore, since the gate electrode is formed so as to face to the pair of sidewall portions, it is possible to manufacture the semiconductor device in which the short channel effect is suppressed.

Furthermore, since the gate insulating film is disposed between the body region including the channel region and the gate electrode, it is possible to manufacture the semiconductor device in which the short channel effect is further suppressed.

In the invention, the linear semiconductor layer is formed on the semiconductor substrate in a spiral form in a plan view. Also, the drain region, the channel region, and the source region are arrayed lengthwise relative to the semiconductor substrate, on the linear semiconductor layer itself or on the linear semiconductor layer and the circumference of the linear semiconductor layer. Also, the gate insulating film and the gate electrode are formed so as to face the channel region. Therefore, a gate width is maximized, the ON current efficiently increases, and it is thereby possible to suppress short channel effect.

Furthermore, since the gate electrode and the linear semiconductor layer are integrated into one body while sandwiching the linear semiconductor layer, it is possible to make the gate width larger.

Furthermore, since the semiconductor device of the invention is the structure that leads the gate electrode from a center of the spiral body to an exterior spiral body, it is easy to wire.

Furthermore, in order to manufacture a MOS transistor in a crystal axis direction orthogonal to a crystal axis parallel to a surface of a semiconductor substrate, it is necessary to form a channel on a drain (source). However, in a conventional ion implantation method after crystal growth, an annealing is necessary to activate dopants, and it is difficult to introduce dopant so as to correspond to the design and to manufacture a vertical MOS transistor having an extremely short channel length.

In the invention, by introducing dopants while producing the crystal growth of a silicon layer, it is possible to realize a vertical MOS transistor having an extremely short channel length.

Furthermore, a wiring structure that is connected with the semiconductor device of the invention is a structure that causes the drain region formed immediately above the surface of the semiconductor substrate to protrude further than a channel region and a source region in a lateral direction. Therefore, it is easy to connect with the semiconductor device.

Furthermore, it is preferable that a gate electrode formed from a polysilicon be formed on the insulating layer of silicon oxide that functions as an etching stop layer. However, for obtaining a sufficient performance as the etching stop layer, the sidewall portions of the linear semiconductor layer that forms the channel region via the gate insulating film must be perfectly parallel with each other. Naturally, it is thereby necessary that an interface of the body region and the drain region that is in contact with the body region, and an interface of the body region and the source region that is in contact with the body region must be perfectly parallel with each other.

Furthermore, it is necessary that the gate insulating film is next to the body region, and the gate electrode is next to the gate insulating film. If the position of the gate electrode is shifted, the performance will be also greatly degraded. Therefore, the position of height of the gate electrode in a direction orthogonal to the substrate and the length of the gate electrode are important factors.

On the other hand, from the viewpoint of parasitic capacitance or the like, the width of the gate electrode in a direction horizontal to the semiconductor substrate is an important factor for improving performance, although it is not as important as the above.

As described above, it is also important to separate the drain region that protrudes from the body region further from the gate electrode.

Therefore, it is important that the drain region is lengthened in a direction orthogonal to the semiconductor substrate and is separated further from the gate electrode.

With regard to wiring to the gate electrode, the structure can be configured to decrease the parasitic capacitance or the like by wiring the gate electrode to the position symmetric to the wiring to the drain region with respect to a spiral center of the linear semiconductor layer that is formed in a spiral form.

With regard to wiring to the source region, the source region may be wired to the center of the spiral body, that is, the position at which an amount of the parasitic capacitance or the like is low.

As the method for introducing dopants while producing the crystal growth, the dopant types are quickly varied and the dopant concentration is directly controlled compared with a conventional ion implantation method.

Therefore, it is possible to dynamically and continuatively determine an accurate concentration gradient of dopant with freedom compared with an ion implantation method. It is thereby easy to design and manufacture impurity diffusion regions. It is possible to design the linear semiconductor layer on which the channel region is formed, an LDD region, or a Pocket region by applying the above characteristic.

In the LDD region, by lowering the dopant concentration compared with the drain or the source, the LDD region can be formed immediately below the source region or immediately above the drain region. Also, it is possible to continuously form the LDD region without two times or the more of ion-implanting.

Therefore, it is possible to reduce the number of steps in the method for introducing dopants while producing the crystal growth compared to an ion-implanting.

Similarly, when also forming the Pocket region or the channel region, it is possible to form the regions by varying the dopant types or dopant concentration.

A HALO layer that is formed in a conventional planar type transistor is unnecessary in a manner similar to an SOI transistor.

As a result, it is possible to reduce the number of steps including a lithography process or an ion implantation process and to calculate a width of a barrier layer in a PN junction with stepped approximation in designing step.

Therefore, it is possible to reduce cost for forming a prototype, designing efficiency, or yields compared with an ion-implanted type transistor.

As described above, as an extremely short channel transistor that is applicable to mass production, the single-gate vertical transistor into which dopants are introduced while producing the crystal growth and which can control the channel regions that are on the front and back sides of the linear semiconductor layer at the same time is most applicable to design and manufacture.

On the other hand, although realizing an extremely short channel length, designing, and manufacturing are difficult, a manufacturing process in which a conventional ion implantation method is applied can be also used.

In this case, since the relative position between a source region and a drain region is offset and a diffusing process by annealing to activate dopants is also necessary, the concentration profile of impurities is broadened, and there is some current reduction caused by influence of electron diffusion due to atoms.

In addition, in order to prevent diffusion of ionic species when introducing ions, and to obtain the electrical insulation, it is necessary to form a STI structure in a manner similar to a planar type transistor.

As described above, according to the invention, it is possible to provide a semiconductor device and a method for manufacturing a semiconductor device in which it is possible to realize an extremely short channel length and to increase the ON current without changing the threshold value.

Furthermore, according to the invention, it is possible to provide a semiconductor device and a method for manufacturing a semiconductor device in which a junction leakage current is suppressed and the number of times of a reflesh operation per hour is reduced.

### BRIEF DESCRIPTION OF THE DRAWINGS

FIGS. 1A to 1C are diagrams illustrating a semiconductor device according to an embodiment of the invention, in which FIG. 1A is a perspective view, FIG. 1B is a cross-sectional view taken along the line A-A′ in FIG. 1A, and FIG. 1C is a cross-sectional view taken along the line B-B′ in FIG. 1A.

FIG. 2 is a schematic cross-sectional view illustrating an example of a semiconductor device according to an embodiment of the invention.

FIGS. 3A to 3D are cross-sectional views illustrating a process step of the method for manufacturing the semiconductor device shown in FIG. 2.

FIGS. 4A to 4D are cross-sectional views illustrating a process step of the method for manufacturing the semiconductor device shown in FIG. 2.

FIGS. 5A and 5B are cross-sectional views illustrating a process step of the method for manufacturing the semiconductor device shown in FIG. 2.

FIG. 6 is a schematic cross-sectional view illustrating another example of a semiconductor device according to an embodiment of the invention.

FIGS. 7A to 7D are cross-sectional views illustrating a process step of the method for manufacturing the semiconductor device shown in FIG. 6.

FIGS. 8A to 8D are cross-sectional views illustrating a process step of the method for manufacturing the semiconductor device shown in FIG. 6.

FIGS. 9A to 9D are cross-sectional views illustrating a process step of the method for manufacturing the semiconductor device shown in FIG. 6.

FIG. 10 is a diagram showing a main part of the semiconductor device according to an embodiment of the invention.

FIG. 11 is a diagram showing a main part of the semiconductor device according to an embodiment of the invention.

FIG. 12 is a graph showing the relationship between a gate voltage and a drain current in the semiconductor device according to the embodiment of the invention.

FIG. 13 is a graph showing the relationship between a drain voltage and a drain current in the semiconductor device according to the embodiment of the invention, the relationship obtained when a gate voltage is varied.

FIG. 14 is a schematic cross-sectional view of a conventional semiconductor device.

### DETAILED DESCRIPTION OF THE INVENTION

Hereinafter, a semiconductor device and a method for manufacturing a semiconductor device according to the invention will be described with reference to the accompanying drawings.

The drawings, which are referred to in the following description, are presented merely for illustration of a semiconductor device or the like of the embodiment, and therefore, the size, thickness, or dimension of each part shown may differ from the actual size, thickness, or dimension of the part in the actual semiconductor device or the like.

### Basic Example of Semiconductor Device

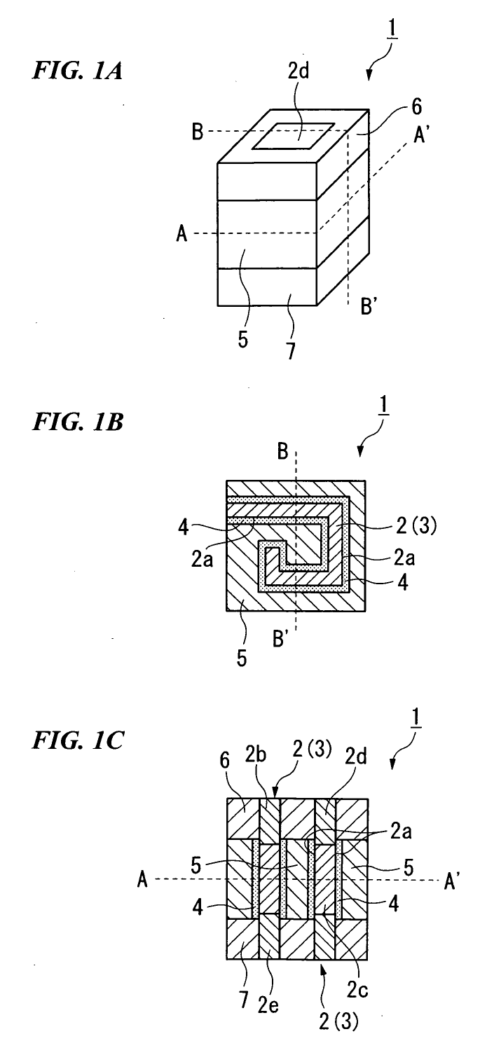

Now referring to FIGS. 1A to 1C, a basic example of a semiconductor device according to the embodiment will be described.

FIG. 1A is a perspective view of the semiconductor device according to the embodiment.

Moreover, FIG. 1B is a cross-sectional view taken along the A-A′ line in FIG. 1A, showing the substrate surface of the semiconductor substrate in a plan view.

Furthermore, FIG. 1C is a cross-sectional view taken along the B-B′ line in FIG. 1A.

The semiconductor device 1 shown in FIG. 1 is generally composed of a spiral body 3 formed by a linear semiconductor layer 2, a gate insulating film 4 formed on the linear semiconductor layer 2, and a gate electrode 5 opposed to the linear semiconductor layer 2 via the gate insulating film 4.

As shown in FIGS. 1B and 1C, the spiral body 3 is formed by the linear semiconductor layer 2 that is substantially protrudent form and that can be said to be substantially rectangular form in cross-sectional view.

The linear semiconductor layer 2 is a semiconductor layer that at least includes a pair of sidewall portions 2a and an upper surface portion 2b, that extends in the longitudinal direction of the sidewall portions 2a or the upper surface portion 2b, and that is bent midway at several locations.

As shown in FIGS. 1B and 1C, the linear semiconductor layer 2 is formed substantially in a spiral form in a plan view.

The height and width of the linear semiconductor layer 2 is substantially constant over the spiral body 3 from the peripheral side to the central side.

The gate insulating film 4 is formed substantially at the center of the linear semiconductor layer 2 in the height direction of the sidewall portions 2a.

The linear semiconductor layer 3 is formed, for example, of impurity-doped silicon, and the gate insulating film 4 is formed, for example, of silicon oxide or silicon oxynitride.

As shown in FIG. 1C, a body region 2c is defined at the approximate center in the height direction of the linear semiconductor layer 2, i.e., at the formation region of the gate insulating film 4, the body region 2c including a channel region of a field effect transistor.

The channel region is formed at the sidewall portion 2a side contacting the gate insulating film 4.

In addition, a source region 2d (first source/drain region) is defined at a portion of the linear semiconductor layer 2 disposed at a position higher than the body region 2c, and a drain region 2e (second source/drain region) is defined at a portion of the linear semiconductor layer 2 disposed at a position lower than the body region 2c.

The body region 2c is formed, for example, of P-type silicon doped with P-type impurities, and the source region 2d and the drain region 2e are formed, for example, of N-type silicon doped with N-type impurities.

The body region 2c may be formed of N-type silicon doped with N-type impurities, and the source region 2d and the drain region 2e may be formed of P-type silicon doped with P-type impurities.

In addition, the gate electrode 5 is formed so as to cover the gate insulating film 4.

As shown in FIGS. 1A to 1C, the gate electrode 5 is formed so as to extend the inner side of the linear semiconductor layer 2 that is wound in a spiral form, and as a result, the gate electrode 5 is at close proximity to the entire surface of the pair of sidewall portions 2a via the gate insulating film 4.

The gate electrode 5 is formed, for example, of polysilicon doped with impurities.

An interlayer insulating film 6 is formed above the gate electrode 5 so as to cover the upper portion of the linear semiconductor layer 2. Meanwhile, another interlayer insulating film 7 is formed below the gate electrode 5 so as to cover the lower portion of the linear semiconductor layer 2.

With such a structure, the source region 2d and the drain region 2e are in such a state that they are covered with the respective interlayer insulating films 6 and 7.

According to the semiconductor device 1 described above, the linear semiconductor layer 2 is formed in a spiral form, the body region 2c is formed in the linear semiconductor layer 2, and the channel region of a field effect transistor is formed in the body region 2c so as to be exposed to the sidewall portions 2a of the linear semiconductor layer 2. It is therefore possible to increase the area of the channel region opposed to the gate insulating film 4 and the gate electrode 5 while suppressing an increase in the area of the linear semiconductor layer 2. As a result, it is possible to suppress an undesirable short channel effect and to increase the ON current.

Exemplary Semiconductor Device

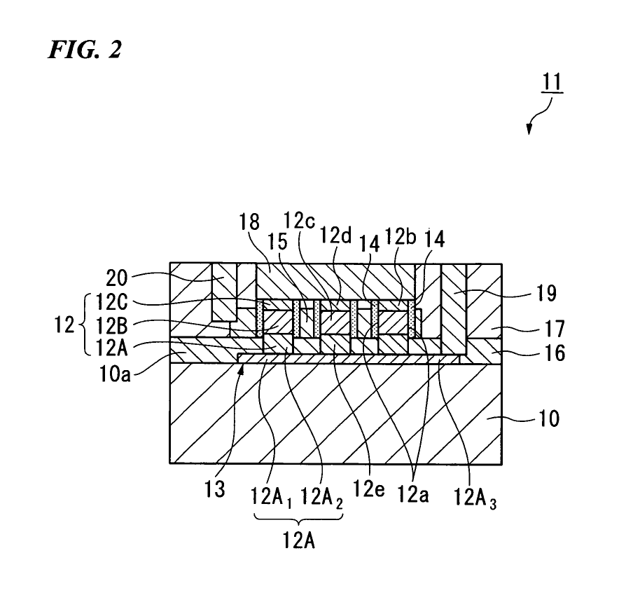

FIG. 2 shows an example of a specific form of the semiconductor device 1 shown in FIG. 1.

The semiconductor device 11 shown in FIG. 2 is generally composed of a semiconductor substrate 10, a spiral body 13 formed of a linear semiconductor layer 12 formed on the semiconductor substrate 10, a gate insulating film 14 formed on the linear semiconductor layer 12, and a gate electrode 15 opposed to the linear semiconductor layer 12 via the gate insulating film 14.

As shown in FIG. 2, the spiral body 13 is formed by the linear semiconductor layer 12 that is substantially protrudent form and that can be said to be substantially rectangular form in cross-sectional view.

The linear semiconductor layer 12 is a semiconductor layer that at least includes a pair of sidewall portions 12a and an upper surface portion 12b, that extends in the longitudinal direction of the sidewall portions 12a or the upper surface portion 12b, and that is bent midway at several locations.

As a result, the linear semiconductor layer 12 is formed in a substantially spiral form when the substrate surface 10a of the semiconductor substrate 10 is viewed in plan view.

The height and width of the linear semiconductor layer 12 is substantially constant over the spiral body 13 from the peripheral side to the central side.

In addition, it is preferable that the pair of sidewall portions 12a of the linear semiconductor layer 12 be parallel with the crystal plane of the single-crystalline silicon that constitutes the semiconductor substrate 10.

The linear semiconductor layer 12 is constructed so that a first semiconductor layer 12A, a second semiconductor layer 12B, and a third semiconductor layer 12C are sequentially laminated therein.

The first semiconductor layer 12A is composed of a lead-out electrode portion 12A₁ (lead-out electrode) formed into a thin-film form on the semiconductor substrate 10 and a projection portion 12A₂ that is projected on the lead-out electrode portion 12A₁ in a spiral form when viewed in plan view.

The lead-out electrode portion 12A₁ and the projection portion 12A₂ are formed of N-type silicon doped with N-type impurities.

Moreover, the second semiconductor layer 12B is formed on the spiral projection portion 12A₂ when the first semiconductor layer 12A is viewed in the plan view, and is shaped substantially in a spiral form when viewed in plan view similar to the shape of the projection portion 12A₂.

The second semiconductor layer 12B is formed of P-type silicon doped with P-type impurities.

Furthermore, the third semiconductor layer 12C is formed on the second semiconductor layer 12B, and is shaped substantially in a spiral form when viewed in plan view similar to the shape of the projection portion 12A₂ of the first semiconductor layer 12A and the second semiconductor layer 12B.

The third semiconductor layer 12C is formed of N-type silicon doped with N-type impurities.

The projection portion 12A₁ of the first semiconductor layer 12A is defined as a drain region 12e of a field effect transistor, the second semiconductor layer 12B is defined as a body region 12c including a channel region, and the third semiconductor layer 12C is defined as a source region 12d.

In this case, it is preferable that an interface of the drain region 12e and the body region 12c, an interface of the source region 12d and the body region 12c, and another crystal face of the single-crystalline silicon that constitute the semiconductor substrate 10 be parallel with each other.

The gate insulating film 14 is formed substantially at the center of the linear semiconductor layer 12 in the height direction of the sidewall portions 12a.

The gate insulating film 14 is formed so as to cover the entirety of the body region 12c and at least a portion of the body regions 12c corresponding to the drain region 12e and the source region 12d.

The gate insulating film 14 is formed, for example, of silicon oxide or silicon oxynitride.

In addition, the gate electrode 15 is formed so as to cover the gate insulating film 14.

As shown in FIG. 2, the gate electrode 15 is formed so as to extend to the inner side of the linear semiconductor layer 12 that is wound in a spiral form, and as a result, the gate electrode 15 is formed in such a way as to surround the linear semiconductor layer 12 so that the gate electrode 15 is at close proximity to the pair of sidewall portions 12a via the gate insulating film 14.

The gate electrode 15 is formed, for example, of polysilicon doped with impurities.

A first interlayer insulating film 17 is formed between the gate electrode 15 and the semiconductor substrate 10.

The first interlayer insulating film 17 is formed so as to cover the entirety of the lead-out electrode portion 12A₁ of the first semiconductor layer 12A and at least a portion of the projection portion 12A₂.

Moreover, a second interlayer insulating film 16 is formed on the first interlayer insulating film 17.

With the first and second interlayer insulating films 17 and 16, the semiconductor substrate 10, the linear semiconductor layer 12 that constitutes the spiral body 13, the gate insulating film 14, and the gate electrode 15 are covered.

As shown in FIG. 2, in the first and second interlayer insulating films 17 and 16, a first contact plug 18 that is connected to the source region 12d of the linear semiconductor layer 12, a second contact plug 19 that is connected to the drain region 12e of the linear semiconductor layer 12, and a gate contact plug 20 that is connected to the gate electrode 15 are formed.

The first contact plug 18 is provided immediately above the spiral body 13 and is laminated on the entire surface of the upper surface 12b of the linear semiconductor layer 12.

The gate contact plug 20 is connected to an end at the peripheral side of the gate electrode 15.

Moreover, the second contact plug 19 passes through the first and second interlayer insulating films 17 and 16 and is connected to the lead-out electrode portion 12A₂ of the first semiconductor layer 12A.

Furthermore, as shown in FIG. 2, the second contact plug 19 is disposed at a position symmetric to the formation position of the gate contact plug 20 with respect to the spiral center of the spiral body 13.

That is, the second contact plug 19 is disposed at an opposite side of the gate contact plug 20 with the spiral body 13 disposed between them.

In order to achieve such an arrangement, the lead-out electrode portion 12A₂ of the first semiconductor layer 12A is formed so that an end 12A₃ thereof extends further out from the peripheral portion of the spiral body 13.

Moreover, the second contact plug 19 is connected to the end 12A₃ of the lead-out electrode portion 12A₂, and as a result, the second contact plug 19 is connected via the lead-out electrode portion 12A₂ to the projection portion 12A₁ of the first semiconductor layer 12A that constitutes the drain region 12e.

According to the semiconductor device 11 described above, the linear semiconductor layer 12 is formed in a spiral form, the body region 12c is formed in the linear semiconductor layer 12, and the channel region of a field effect transistor is formed in the body region 12c so as to be exposed to the sidewall portions 12a of the linear semiconductor layer 12. It is therefore possible to increase the area of the channel region opposed to the gate insulating film 14 and the gate electrode 15 while suppressing an increase in the area of the linear semiconductor layer 12. As a result, it is possible to suppress an undesirable short channel effect and to increase the ON current.

In addition, since the first contact plug 18, the second contact plug 19, and the gate contact plug 20 are separated from each other, it is possible to decrease the parasitic capacitance between the contact plugs 18 to 20.

Furthermore, since the spiral body 13 having the channel region 12c is covered with the first and second interlayer insulating films 17 and 16, it is possible to construct a perfect depletion type transistor.

Method for Manufacturing Exemplary Semiconductor Device

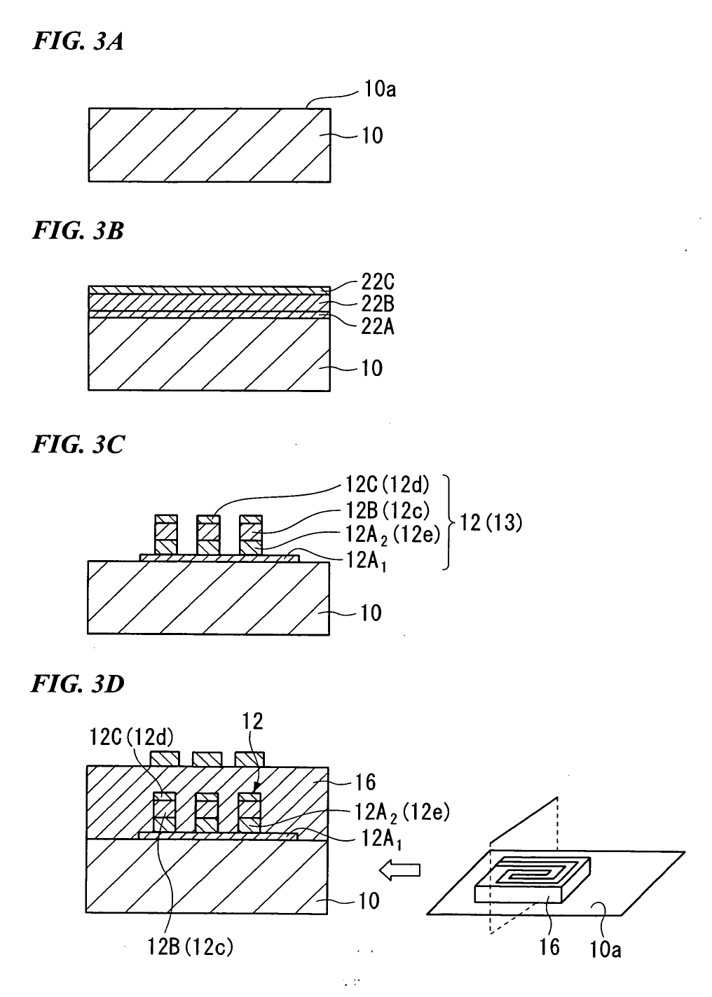

Referring now to FIGS. 3 to 5, the method for manufacturing the semiconductor device 11 shown in FIG. 2 will be described.

The method generally includes a step of sequentially forming on a semiconductor substrate, a first semiconductor film, a second semiconductor film, and a third semiconductor film, a step of forming a spiral body, a step of forming a gate insulating film, and a step of forming a gate electrode.

First, in the step of forming the first to third semiconductor films, as shown in FIG. 3A, a semiconductor substrate 10 formed, for example, of single-crystalline silicon is prepared.

Then, surface cleaning (including APM cleaning and SPM cleaning) is performed on the substrate surface 10a to thereby remove a natural oxide film or particles originally adhering to the substrate surface 10a, and thereafter, the semiconductor substrate 10 is left in the state where a natural oxide film is formed on the substrate surface 10a.

Next, as shown in FIG. 3B, a first semiconductor film 22A, a second semiconductor film 22B, and a third semiconductor film 22C are sequentially laminated.

The forming of the first to third semiconductor films 22A to 22C is carried out by forming a silicon film and introducing impurities as a dopant element at the same time.

Specifically, in order to remove the natural oxide film on the semiconductor substrate 10, the semiconductor substrate 10 is heated in a vacuum chamber at a temperature greater than or equal to 1200 degrees to thereby expose the surface of the silicon atoms.

Next, the semiconductor substrate 10 is heated at a temperature of approximately 1100 degrees, which is the crystal growth temperature of the silicon.

Then, while growing a single-crystalline silicon by a CVD method using a raw material gas such as SiH₄, SiH₂Cl₂, SiHCl₃, SiCl₄, or the like N-type impurities such as PH₃, AsH₃, or the like are introduced so that the dopant concentration becomes approximately 1×10¹⁵ to approximately 1×10²² cm⁻³ to thereby form the first semiconductor film 22A.

In a similar manner, while growing the single-crystalline silicon, P-type impurities such as B₂H₆ are introduced so that the dopant concentration becomes approximately 1×10¹⁵ to approximately 1×10²² cm⁻³ to thereby form the second semiconductor film 22B.

In addition, while growing the single-crystalline silicon, N-type impurities such as PH₃ or AsH₃ are introduced so that the dopant concentration becomes approximately 1×10¹⁵ to approximately 1×10²² cm⁻³ to thereby form the third semiconductor film 22C.

In this manner, the first to third semiconductor films 22A to 22C are sequentially laminated.

The total thickness of the first to third semiconductor films 22A to 22C needs to a predetermined thickness and is desirably set to approximately 50 nm, for example.

With this thickness, the distance between a gate electrode and a drain region or a source region can be set to be as large as possible, and it is therefore possible to decrease the parasitic capacitance.

In addition, instead of using the CVD method, an MBE method using a solid silicon source may be used.

Even in this case, P, As, B, and the like may be used as the P or N-type impurities.

In addition, as methods for removing the natural oxide film, instead of using the heating chamber, a method may be used for removing the natural oxide film by etching using a multi-chamber or the like.

Next, in the step of forming the spiral body 13, as shown in FIG. 3C, portions of the third semiconductor film 22C, the second semiconductor film 22B, and the first semiconductor film 22A are patterned to thereby form a linear semiconductor layer 12 that is substantially protrudent form as viewed in cross-sectional view, and the linear semiconductor layer 12 is processed in a substantially spiral form when the substrate surface 10a of the semiconductor substrate 10 is viewed in plan view, whereby a spiral body 13 is formed from the linear semiconductor layer 12.

Specifically, a resist is applied onto the third semiconductor film 22C, and exposure is performed using a reticle, whereby a resist pattern is formed on the third semiconductor film 22C.

Thereafter, anisotropic dry etching is carried out along the resist pattern, whereby the third semiconductor film 22C, which is the first layer from the top, and the second semiconductor film 22B, which is the second layer from the top, are removed, while the first semiconductor film 22A, which is the third layer from the top, is left with a thickness of approximately 10 nm.

As an alternative method, the third semiconductor film 22C is annealed so that a thick oxide film thicker than the natural oxide film is formed on the upper surface of the third semiconductor film 22C, the thick oxide film serving as a hard mask layer.

Subsequently, a resist is applied thereon, and exposure is performed using a reticle, whereby a resist pattern is formed on the hard mask layer.

Thereafter, a hard mask of an oxide film is formed by performing dry etching along the resist pattern.

Finally, anisotropic wet etching is carried out using an alkali solution such as TMAH (Tetra methyl ammonium hydroxide), whereby the third semiconductor film 22C, which is the first layer from the top, and the second semiconductor film 22B, which is the second layer from the top, are removed, while the first semiconductor film 22A, which is the third layer from the top, is left with approximately 10 nm of thickness.

In this manner, the spiral body 13 formed by the linear semiconductor layer 12 is formed.

Here, as shown in FIG. 3C, the remaining portion of the third semiconductor film 22C, which is the first layer from the top, is defined as the third semiconductor layer 12C having the source region 12d, while the remaining portion of the second semiconductor film 22B is defined as the second semiconductor layer 12B having the body region 12c.

In addition, among the remaining portion of the first semiconductor film 22A, the thin film having a thickness of approximately 10 nm at the semiconductor substrate 10 side is defined as the lead-out electrode portion 12A₁, and a portion projected from the thin film having a thickness of approximately 10 nm is defined as the projection portion 12A₂ having a drain region 12e.

Next, as shown in FIG. 3D, the first interlayer insulating film 17 is formed at a thickness of approximately 25 nm to approximately 40 nm so as to cover the semiconductor substrate 10 and the linear semiconductor layer 12.

Specifically, the first interlayer insulating film is formed by a CVD method using a raw material gas such as TEOS (Tetra ethoxy silane).

Moreover, the first interlayer insulating film may be formed by a SOG (Spin On Glass) method using Low-K material, which has low dielectric constant.

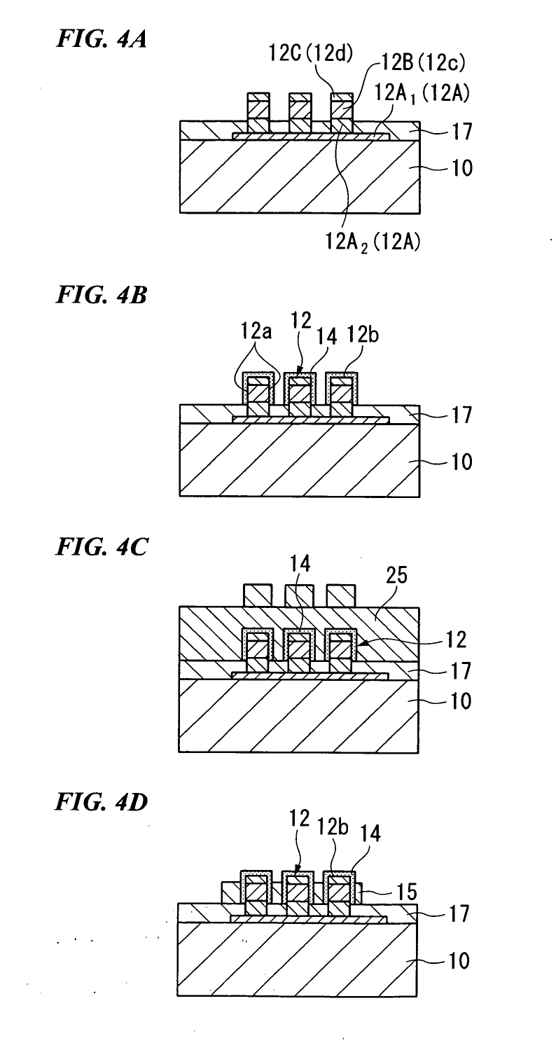

Next, the unevenness of the upper surface of the first interlayer insulating film 17 is planarized by a CMP process. Moreover, as shown in FIG. 4A, the first interlayer insulating film 17 is etched back until the third semiconductor layer 12C and the second semiconductor layer 12B are completely exposed. In addition, the first interlayer insulating film 17 is further etched back to a thickness of approximately 3 nm to approximately 7 nm closer to the first semiconductor layer 12A than the interface of the second semiconductor layer 12B and the first semiconductor layer 12A.

The thus-formed first interlayer insulating film 17 functions as an interlayer insulating film between semiconductor devices or interconnections.

Next, in the gate insulating film forming step, a gate insulating film is formed at least in a pair of sidewall portions of the linear semiconductor layer.

Specifically, as shown in FIG. 4B, a CVD process or an annealing process under oxidation atmosphere is performed on the linear semiconductor layer 12 that is exposed on the first interlayer insulating film 17, whereby a gate insulating film 14 having a thickness of between approximately 1 nm and approximately, 10 nm is formed on the pair of sidewall portions 12a and the upper surface 12b of the linear semiconductor layer 12.

In the case of using annealing under an oxidation atmosphere, the surface of the linear semiconductor layer 12 is dry-oxidized in an oxidation furnace, whereby a gate insulating film 14 formed from a silicon oxide film is formed.

In the case of using the CVD process, by using a raw material gas such as TEOS (Tetra ethoxy silane), an insulation material such as SiO₂ or a High-K film having a high dielectric constant such as HfO₂ is deposited.

Next, in the gate electrode forming step, a gate electrode 15 opposed to the pair of sidewall portions 12a via the gate insulating film 14 is formed.

Specifically, as shown in FIG. 4C, a polysilicon layer 25 is formed by a CVD method so as to cover the first interlayer insulating film 17, the linear semiconductor layer 12, and the gate insulating film 14.

Subsequently, the unevenness of the upper surface of the polysilicon layer 25 is planarized by a CMP process. Thereafter, as shown in FIG. 4D, the polysilicon layer 25 is etched back until a portion of the gate insulating film 14 formed on the upper surface 12b of the linear semiconductor layer 12 is exposed.

Moreover, a portion of the polysilicon layer 25 disposed at the outer side of the peripheral portion of the spiral body 13 is etched and removed.

In this way, the gate electrode 15 is formed.

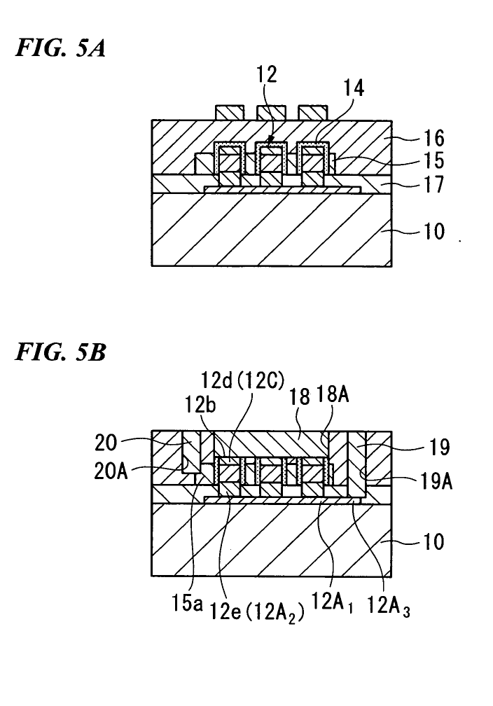

Next, as shown in FIG. 5A, a second interlayer insulating film 16 is formed so as to cover the first interlayer insulating film 17, the linear semiconductor layer 12, the gate insulating film 14, and the gate electrode 15.

Specifically, the first interlayer insulating film is formed by a CVD method using a raw material gas such as TEOS (Tetra ethoxy silane).

Moreover, the first interlayer insulating film may be formed by a SOG (Spin On Glass) method using Low-K material, which has a low dielectric constant.

Next, the unevenness of the upper surface of the second interlayer insulating film 16 is planarized by a CMP process. Moreover, as shown in FIG. 5B, the second interlayer insulating film 16 and the first interlayer insulating film 17 are etched to thereby form a through-hole 19A so that the end 12A₃ of the lead-out electrode portion 12A₁ is exposed.

In a similar manner, the second interlayer insulating film 16 is etched to thereby form a through-hole 20A so that the end 15a of the gate electrode 15 is exposed.

In addition, portions of the second interlayer insulating film 16 and the gate insulating film 14 are etched to thereby form a through-hole 18A so that the upper surface 12b of the linear semiconductor layer 12 is exposed.

Thereafter, polysilicon in which P or N-type dopant impurities (P, As, B, and the like) are introduced is filled into the through-holes 18A to 20A by a CVD method.

Instead of using polysilicon, a metal such as tungsten may be filled in the through-holes 18A to 20A.

As a result of the filling process, a first contact plug 18 that is connected to the source region 12d of the linear semiconductor layer 12, a second contact plug 19 that is connected to the drain region 12e of the linear semiconductor layer 12, and a gate contact plug 20 that is connected to the gate electrode 15 are formed.

In this way, the semiconductor device 11 shown in FIG. 2 is manufactured.

According to the method for manufacturing the semiconductor device 11 described above, the first to third semiconductor films 22A to 22C are sequentially formed which will constitute the drain region 12e, the body region 12c, and the source region 12d, respectively. It is therefore possible to control the impurity concentration in each region in a simple manner. Accordingly, it is possible to simplify the design of the semiconductor device 11.

In addition, the spiral body 13 formed from the linear semiconductor layer 12 is formed to thereby form the gate insulating film 14 in the pair of sidewall portions 12a of the linear semiconductor layer 12, and the gate electrode 15 is formed so as to be opposed to the pair of sidewall portions 12a via the gate insulating film 14. Therefore, the area of the linear semiconductor layer 12 including the channel region is decreased; therefore, it is possible to manufacture a small semiconductor device 11 to thereby realize a high integration LSI circuit.

In addition, by employing the spiral structure, it is easy to increase the length of the linear semiconductor layer 12. Therefore, it is possible to increase the area of the channel region opposed to the gate electrode 15 and to thus manufacture the semiconductor device 11 having a large ON current.

### Another Exemplary Semiconductor Device

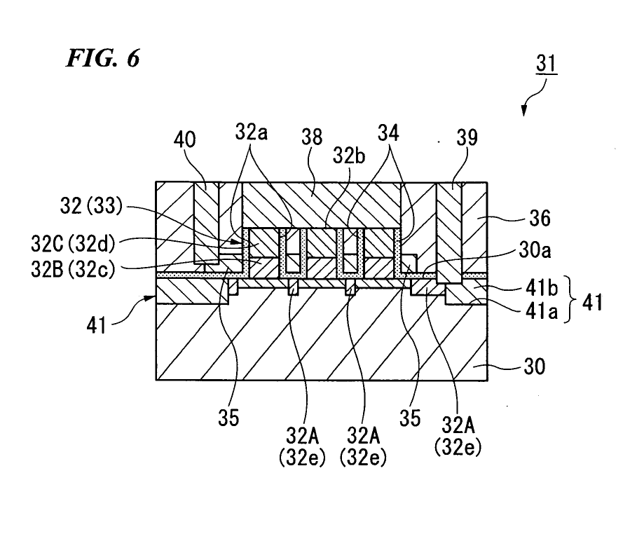

FIG. 6 shows another example of a specific form of the semiconductor device 1 shown in FIG. 1.

The semiconductor device 31 shown in FIG. 6 is generally composed of a semiconductor substrate 30, a spiral body 33 formed by a linear semiconductor layer 32 formed on the semiconductor substrate 30, a gate insulating film 34 formed on the linear semiconductor layer 32, and a gate electrode 35 opposed to the linear semiconductor layer 32 via the gate insulating film 34.

As shown in FIG. 6, the spiral body 33 is formed by the linear semiconductor layer 32 that is substantially protrudent form and that can be said to be substantially rectangular form in cross-sectional view.

The linear semiconductor layer 32 is a semiconductor layer that at least includes a pair of sidewall portions 32a and an upper surface portion 32b, that extends in the longitudinal direction of the sidewall portions 32a or the upper surface portion 32b, and is bent midway at several locations.

As a result, the linear semiconductor layer 32 is formed in a substantially spiral form when the substrate surface 30a of the semiconductor substrate 30 is viewed in a plan view.

The height and width of the linear semiconductor layer 32 is substantially constant over the spiral body 33 from the peripheral side to the central side.

Moreover, the linear semiconductor layer 32 is projected from the substrate surface 30a of the semiconductor substrate 30.

A P-type silicon portion 32B in which P-type impurities are ion-implanted is formed at the semiconductor substrate 30 side of the linear semiconductor layer 32.

The P-type silicon portion 32B is formed in such a state that a portion thereof is diffused to the inside of the semiconductor substrate 30.

Moreover, an N-type silicon layer 32C in which N-type impurities are ion-implanted is formed above the P-type silicon portion 32B.

Furthermore, an N-type silicon portion 32A in which N-type impurities are ion-implanted is formed in a portion of the semiconductor substrate 30 adjacent to the P-type silicon portion 32B.

In addition, the P-type silicon portion 32B is defined as a body region 32c including the channel region that constitutes a field effect transistor. The N-type silicon portion 32C above the P-type silicon portion 32B is defined as a source region 32d, and the N-type silicon portion 32A of the semiconductor substrate 30 is defined as a drain region 32e.

Moreover, a gate insulating film 34 is formed on the sidewall portions 32a of the linear semiconductor layer 32 and the N-type silicon portion 32A of the semiconductor substrate 30.

The gate insulating film 34 is formed so as to cover the entirety of the body region 32c, the entirety of the drain region 32e, and a portion of the source region 32d at the sidewall portions 32a.

The gate insulating film 34 is formed, for example, of silicon oxide or silicon oxynitride.

In addition, the gate electrode 35 is formed on the semiconductor substrate 30 so as to cover the gate insulating film 34.

As shown in FIG. 6, the gate electrode 35 is formed so as to extend the inner side of the linear semiconductor layer 32 that is wound in a spiral form, and as a result, the gate electrode 35 is formed in such a way as to surround the linear semiconductor layer 32 so that the gate electrode 35 is at close proximity to the pair of sidewall portions 32a via the gate insulating film 34.

The gate electrode 35 is formed, for example, of polysilicon doped with impurities.

In addition, an interlayer insulating film 36 is formed so as to cover the semiconductor substrate 30, the linear semiconductor layer 32, the gate insulating film 34, and the gate electrode 35.

Furthermore, as shown in FIG. 6, in the interlayer insulating film 36, a first contact plug 38 that is connected to the source region 32d of the linear semiconductor layer 32, a second contact plug 39 that is connected to the drain region 32e of the linear semiconductor layer 32, and a gate contact plug 40 that is connected to the gate electrode 35 are formed.

The first contact plug 38 is provided immediately above the spiral body 33 and is bonded to the entire surface of the upper surface 32b of the linear semiconductor layer 32.

The gate contact plug 40 is connected an end at the peripheral side of the gate electrode 35.

Moreover, the second contact plug 39 is connected to the N-type silicon portion 32A of the semiconductor substrate 30.

Furthermore, as shown in FIG. 6, the second contact plug 39 is disposed at a position symmetric to the formation position of the gate contact plug 40 with respect to the spiral center of the spiral body 33.

That is, the second contact plug 39 is disposed at a side opposite to the gate contact plug 40 with the spiral body 33 disposed between them.

Moreover, an element isolation portion 41 having an STI structure is formed in the vicinity of the N-type silicon portion 32A of the semiconductor substrate 30.

The element isolation portion 41 is composed of a trench 41a formed in the semiconductor substrate 30 and an insulation layer 41b formed from silicon oxide filled into the trench 41a.

According to the semiconductor device 31 described above, it is possible to obtain substantially the same advantages as the semiconductor device 11 shown in FIG. 2.

Method for Manufacturing Another Exemplary Semiconductor Device

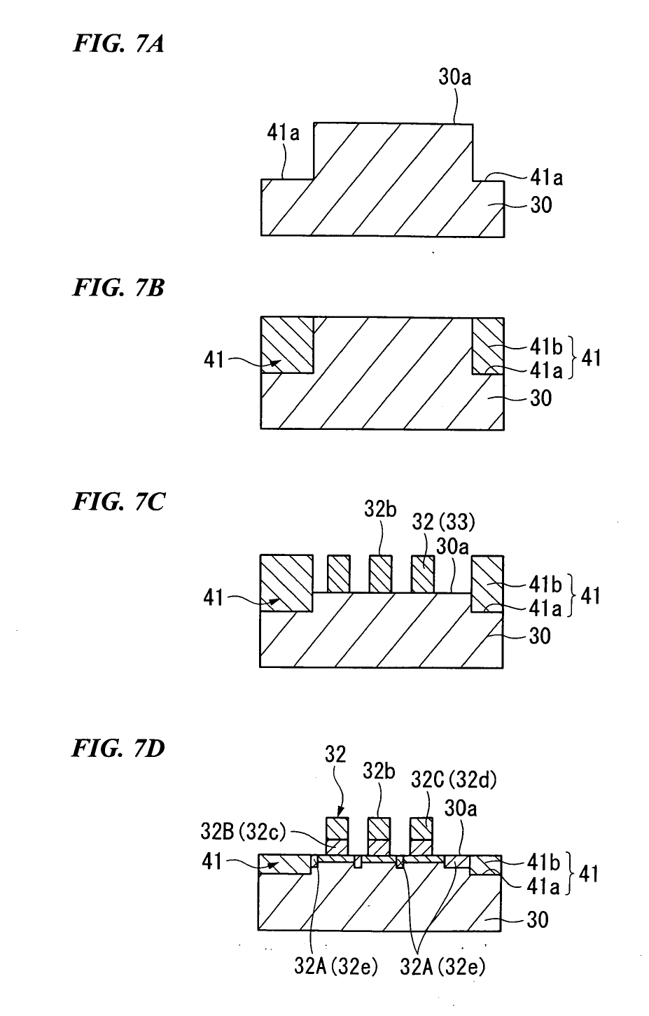

Referring now to FIGS. 7 to 9, the method for manufacturing the semiconductor device 31 shown in FIG. 6 will be described.

The method generally includes a step of patterning a substrate surface of a semiconductor substrate to thereby form a linear semiconductor layer that is substantially protrudent form in a cross-sectional view and that is shaped substantially in a spiral form, a step of forming a drain region in the semiconductor substrate in the vicinity of the linear semiconductor layer and forming a body region and a source region in the linear semiconductor layer, a step of forming a gate insulating film, and a step of forming a gate electrode.

First, as shown in FIG. 7A, a semiconductor substrate 30 formed of single-crystalline silicon is prepared.

Then, surface cleaning (including APM cleaning and SPM cleaning) is performed on the substrate surface 30a, whereby the semiconductor substrate 30 is left in a state where a natural oxide film is formed on the substrate surface 30a.

Subsequently, a resist is applied onto the substrate surface 30a, and exposure is performed using a reticle, whereby a resist pattern is formed on the substrate surface 30a.

Thereafter, dry etching is carried out on the semiconductor substrate 30 along the resist pattern to thereby form a trench 41a.

Next, as shown in FIG. 7B, an insulation layer 41b formed from an oxide film is deposited in the trench 41a by a CVD method using a raw material gas such as TEOS, and the insulation layer 41b is planarized by an etching or CMP process.

In this way, the element isolation portion 41 is formed.

Next, as a step of forming the linear semiconductor layer 32, the substrate surface 30a of the semiconductor substrate 30 is etched to thereby form the linear semiconductor layer 32 in a substantially spiral form as viewed in a plan view.

Specifically, a resist is applied onto the substrate surface 30a, and exposure is performed using a reticle, whereby a resist pattern is formed on the substrate surface 30a.

Thereafter, the semiconductor substrate 30a is dry-etched along the resist pattern.

As an alternative method, the substrate surface 30a is annealed so that a thick oxide film thicker than the natural oxide film is formed thereon, the thick oxide film serving as a hard mask layer.

Subsequently, a resist is applied thereon, and exposure is performed using a reticle, whereby a resist pattern is formed on the hard mask layer.

Thereafter, a hard mask of an oxide film is formed by performing dry etching along the resist pattern.

Finally, anisotropic wet etching is carried out using an alkali solution such as TMAH (Tetra methyl ammonium hydroxide), whereby the linear semiconductor layer 32 is formed in a substantially spiral form as viewed in plan view.

In this way, the linear semiconductor layer 32 is formed, and in this case, the substrate surface of the semiconductor substrate before the etching is performed serves as the upper surface 32b of the linear semiconductor layer 32.

In addition, the substrate surface 30a of the semiconductor substrate after the etching is performed is a surface newly formed by the etching.

Next, in a step of forming the drain region, the body region, and the source region, N-type impurities, P-type impurities, and N-type impurities are sequentially ion-implanted to the semiconductor substrate 30 and the linear semiconductor layer 32, whereby a drain region 32e formed from the N-type silicon portion 32A, a body region 32c formed from the P-type silicon portion 32B, and a source region 32d formed from the N-type silicon portion 32C are formed.

Specifically, in order to remove the natural oxide film thereon, the semiconductor substrate 30 and the linear semiconductor layer 32 are heated in a vacuum chamber at a temperature greater than or equal to 1200 degrees to thereby expose the surface of the silicon atoms.

Next, N-type impurities such as P or As are ion-implanted under the condition of 100 to 0.1 keV so that the dopant concentration becomes between approximately 1×10¹⁵ and approximately 1×10²² cm⁻³ to thereby form the N-type silicon portion 32A in the semiconductor substrate 30.

Subsequently, P-type impurities such as B are ion-implanted under the condition of 100 to 0.1 keV so that the dopant concentration becomes between approximately 1×10¹⁵ and approximately 1×10²² cm⁻³ to thereby form the P-type silicon portion 32B in the semiconductor substrate 30 and the linear semiconductor layer 32.

By the ion-implantation of the P-type impurities, the P-type silicon portion 32B is diffused to the semiconductor substrate 30 side so that the diffused portion becomes adjacent to the N-type silicon portion 32A.

Furthermore, N-type impurities such as P or As are ion-implanted under conditions of 100 to 0.1 keV so that the dopant concentration becomes between approximately 1×10¹⁵ and approximately 1×10²² cm⁻³ to thereby form the N-type silicon portion 32C on the P-type silicon portion 32B of the linear semiconductor layer 32.

In this manner, the drain region 32e formed from the N-type silicon portion 32A, the body region 32c formed from the P-type silicon portion 32B, and the source region 32d formed from the N-type silicon portion 32C are formed.

In addition, as shown in FIG. 7D, the insulation layer 41b of the element isolation portion 41 is etched so that the upper surface of the insulation layer 41b is on the same surface as the substrate surface 30a of the semiconductor substrate 30.

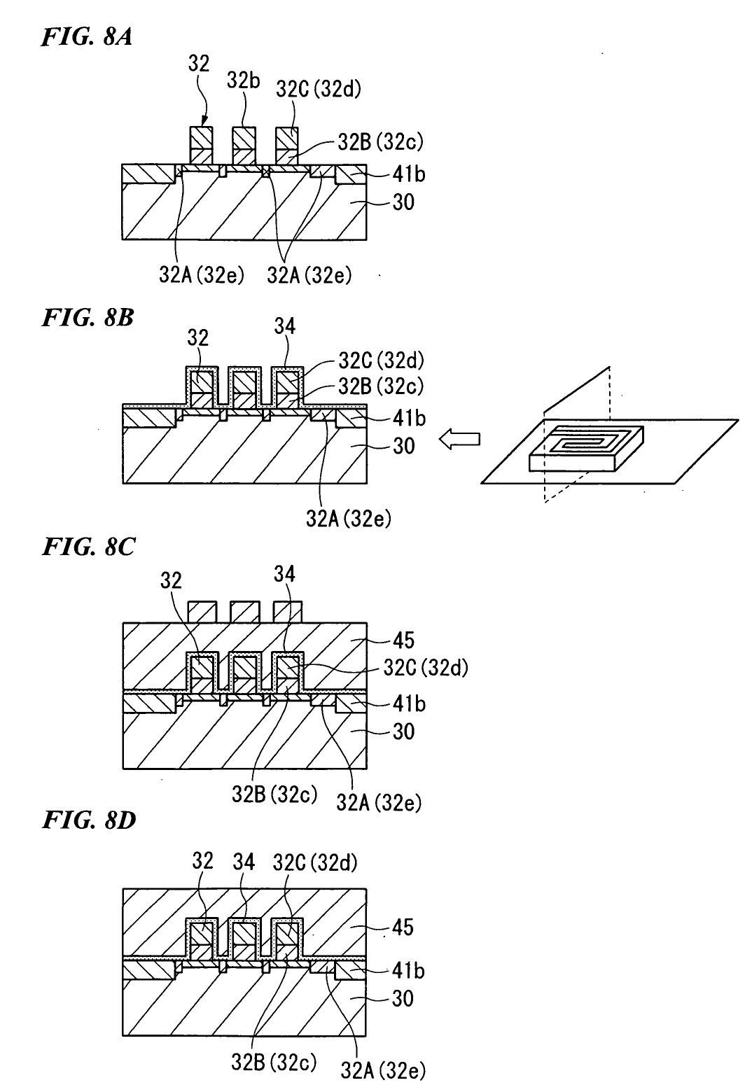

Next, as shown in FIG. 8A, the grooves between the linear semiconductor layers 32 are etched so that the groove widths are increased and the width of the linear semiconductor layer 32 is decreased.

Specifically, a resist is applied onto the upper surface 32b of the linear semiconductor layer 32, and exposure is performed using a reticle, whereby a resist pattern is formed on the upper surface 32b.

Thereafter, the linear semiconductor layer 32 is dry-etched along the resist pattern.

Alternatively, in a manner similar to the method shown in FIG. 7C, the linear semiconductor layer 32 is anisotropically wet-etched using TMAH or the like.

Next, as shown in FIG. 8B, as a gate insulating film forming step, a gate insulating film 34 is formed on the semiconductor substrate 30 and the linear semiconductor layer 32.

Specifically, as shown in FIG. 8B, a CVD process or an annealing process under oxidation atmosphere is performed on the semiconductor substrate 30 and the linear semiconductor layer 32, whereby a gate insulating film 34 having a thickness of approximately 1 nm to approximately 7 nm is formed.

In the case of using the annealing under oxidation atmosphere, the substrate surface of the semiconductor substrate 30 and the surface of the linear semiconductor layer 32 are dry-oxidized in an oxidation furnace, whereby the gate insulating film 34 formed from a silicon oxide film is formed.

In the case of using the CVD process, by using a raw material gas such as TEOS (Tetra ethoxy silane), an insulation material such as SiO₂ or a High-K film having a high dielectric constant such as HfO₂ is deposited.

Next, in the gate electrode forming step, a gate electrode 35 opposed to the sidewall portions 32a of the linear semiconductor layer 32 via the gate insulating film 34 is formed.

Specifically, as shown in FIG. 8C, a polysilicon layer 45 is formed by a CVD method so as to cover the semiconductor substrate 30, the linear semiconductor layer 32, and the gate insulating film 34.

Subsequently, as shown in FIG. 8D, the unevenness of the upper surface of the polysilicon layer 45 is planarized by a CMP process.

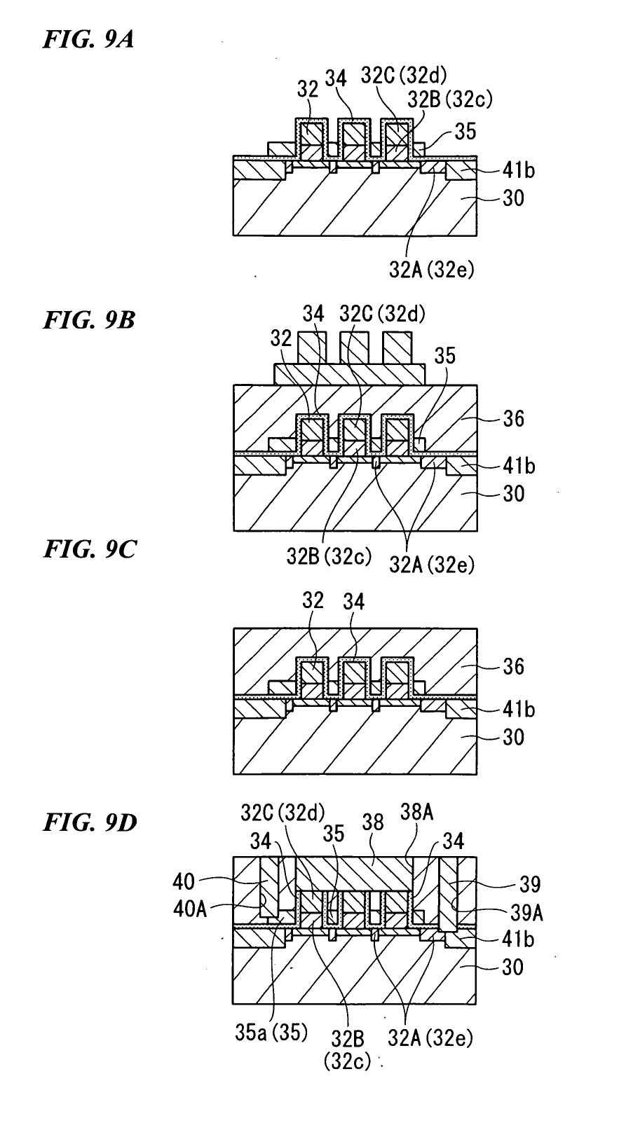

Thereafter, as shown in FIG. 9A, the polysilicon layer 45 is etched back until a portion of the gate insulating film 34 adjacent to the N-type silicon portion 32C (source region 32d) is exposed.

Moreover, a portion of the polysilicon layer 45 disposed at the outer side of the peripheral portion of the spiral body 33 is etched and removed.

In this way, the gate electrode 35 is formed.

Next, as shown in FIG. 9B, an interlayer insulating film 36 is formed so as to cover the semiconductor substrate 30, the linear semiconductor layer 32, the gate insulating film 34, and the gate electrode 35.

Specifically, the first interlayer insulating film is formed by a CVD method using a raw material gas such as TEOS (Tetra ethoxy silane).

Moreover, the first interlayer insulating film may be formed by a SOG (Spin On Glass) method using Low-K material, which has low dielectric constant.

Next, as shown in FIG. 9C, the unevenness of the upper surface of the interlayer insulating film 36 is planarized by a CMP process.

Thereafter, as shown in FIG. 9D, the interlayer insulating film 36 is etched to thereby form a through-hole 39A so that the N-type silicon portion 32A (drain region 32e) is exposed.

Similarly, the interlayer insulating film 36 is etched to thereby form a through-hole 40A so that the end 35a of the gate electrode 35 is exposed.

In addition, portions of the interlayer insulating film 36 and the gate insulating film 34 are etched to thereby form a through-hole 38A so that the upper surface 32b of the linear semiconductor layer 32 is exposed.

Thereafter, polysilicon in which P or N-type dopant impurities (P, As, B, and the like) are introduced is filled into the through-holes 38A to 40A by a CVD method.

Instead of using polysilicon, metal such as tungsten may be filled in the through-holes 38A to 40A.

As a result of the filling process, a first contact plug 38 that is connected to the source region 32d of the linear semiconductor layer 32, a second contact plug 39 that is connected to the drain region 32e of the linear semiconductor layer 32, and a gate contact plug 40 that is connected to the gate electrode 35 are formed.

In this way, the semiconductor device 31 shown in FIG. 6 is manufactured.

According to the method for manufacturing the semiconductor device 31 described above, the spiral body 33 formed from the linear semiconductor layer 32 is formed to thereby form the gate insulating film 34 in the pair of sidewall portions 32a of the linear semiconductor layer 32, and the gate electrode 35 is formed so as to be opposed to the pair of sidewall portions 32a via the gate insulating film 34. Therefore, the area of the linear semiconductor layer 32 including the channel region is decreased; therefore, it is possible to manufacture a small semiconductor device 31 to thereby realize a high integration LSI circuit.

In addition, by employing the spiral structure, it is easy to increase the length of the linear semiconductor layer 32. Therefore, it is possible to increase the area of the channel region opposed to the gate electrode 35 and to thus manufacture the semiconductor device 31 having a large ON current.

In the example described above, the semiconductor device has been described as having a spiral body that has a spiral form in plan view and that is generally rectangular form in overall shape. However, the invention is not limited to such a form.

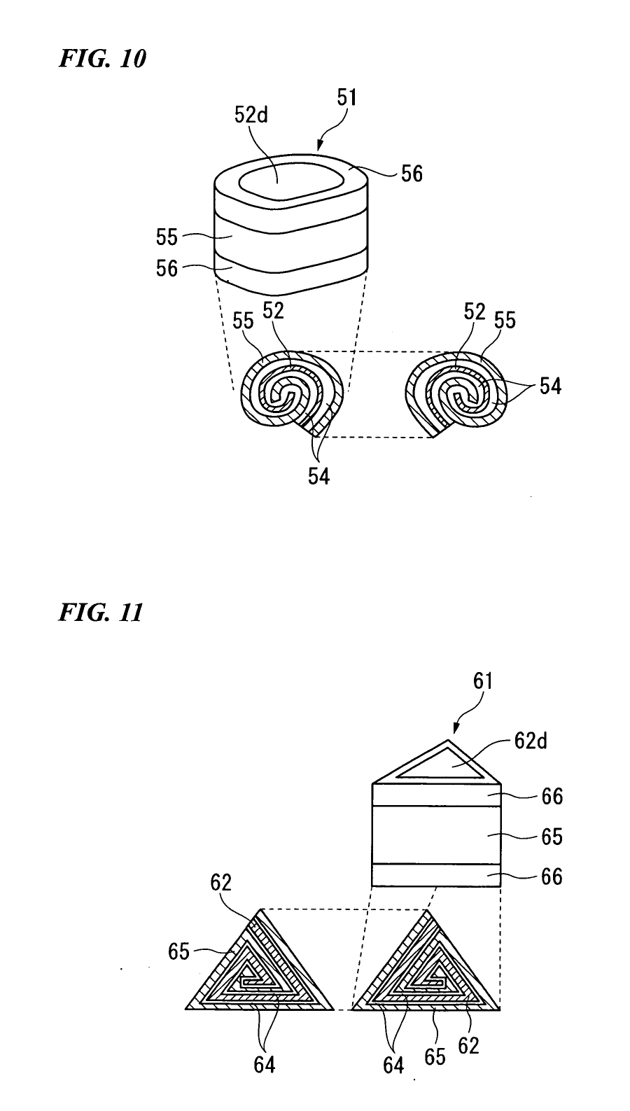

For example, as shown in FIG. 10, a spiral body may be employed that has a spiral form in plan view and is generally circular (including non-perfect circle) in overall shape. Moreover, as shown in FIG. 11, a spiral body may be employed that has a spiral form in plan view and that is generally triangular in overall shape.

In addition, the winding direction of the spiral body may be clockwise (right-turn) or counterclockwise (left-turn).

In addition, the spiral body 51 shown in FIG. 10 is formed from a linear semiconductor layer 52 that has a spiral form in plan view and that is generally rectangular form in overall shape. A gate insulating film 54 is formed in the linear semiconductor layer 52, and a gate electrode 55 opposed to the linear semiconductor layer 52 via the gate insulating film 54 is provided.

Moreover, a source region 52d is defined at the upper portion of the linear semiconductor layer 52 in the height direction, a body region including a channel region is defined at the center in the height direction, and a drain region is defined at the lower portion in the height direction.

Furthermore, interlayer insulating films 56 are formed below and above the gate electrode.

According to the semiconductor device having the spiral body 51, since the pair of sidewall portions of the linear semiconductor layer 52 is formed of a round surface, it is possible to realize a structure that is not sensitive to an electric field.

In addition, the spiral body 61 shown in FIG. 11 is formed from a linear semiconductor layer 62 that has a spiral form in plan view and is generally triangular in overall shape. A gate insulating film 64 is formed in the linear semiconductor layer 62, and a gate electrode 65 opposed to the linear semiconductor layer 62 via the gate insulating film 64 is provided.

Moreover, a source region 62d is defined at the upper portion of the linear semiconductor layer 62 in the height direction, a body region including a channel region is defined at the center in the height direction, and a drain region is defined at the lower portion in the height direction.

Furthermore, interlayer insulating films 66 are formed below and above the gate electrode.

According to the semiconductor device having the spiral body 61, it is possible to obtain substantially the same advantages as the above-described semiconductor device 1, 11, and 31.

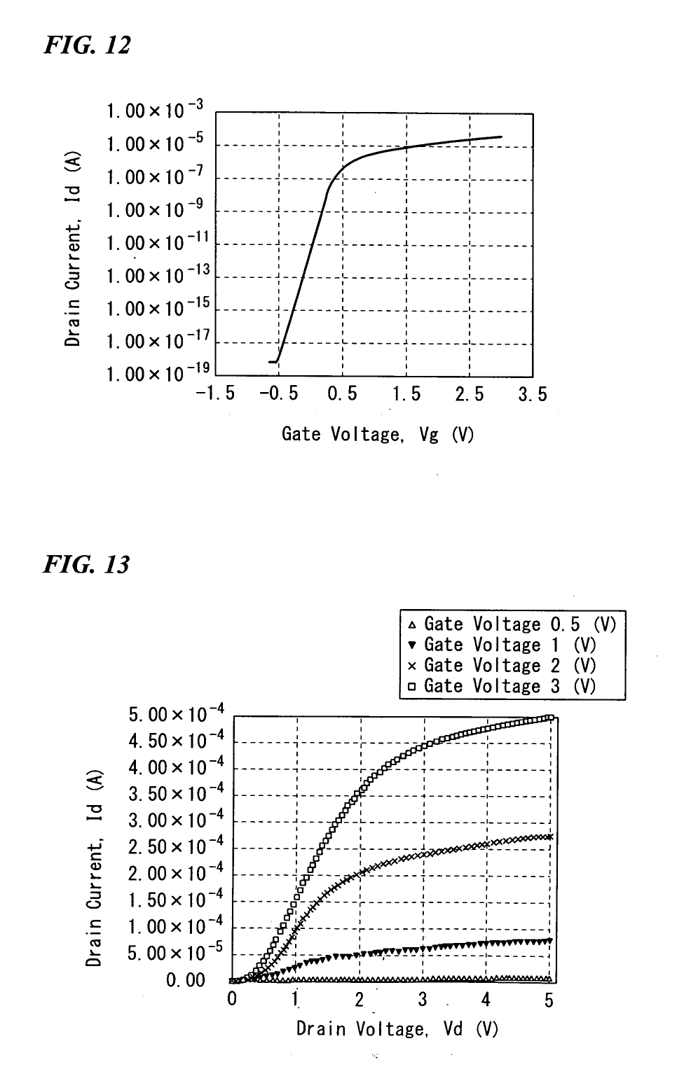

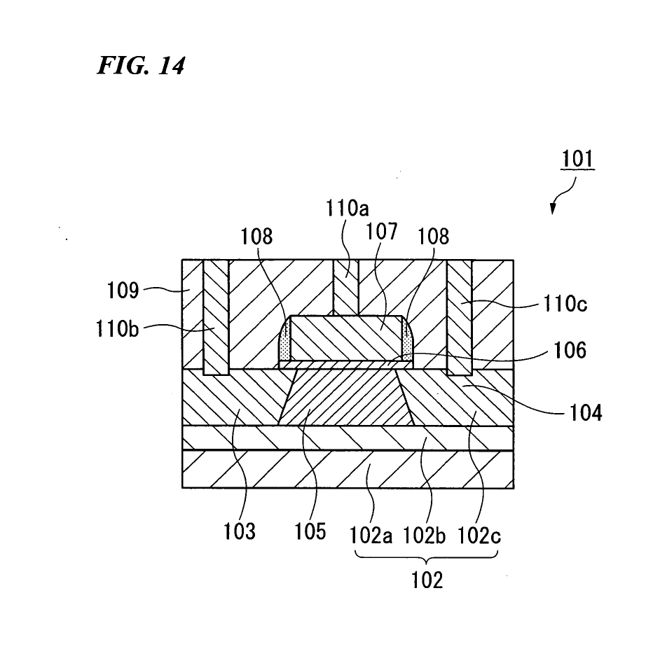

FIGS. 12 and 13 show the electrical characteristics of the semiconductor device shown in FIG. 2.

The semiconductor device has such a structure that a gate length is approximately 45 nm, a gate width is approximately 220 nm, the width of a linear semiconductor layer is approximately 20 nm, the thickness of a gate insulating film is approximately 5 nm, a body region including a channel region is of a P type and has a carrier density of approximately 1×10¹⁵ cm⁻³, and a source region and a drain region are of an N type and have a carrier density of approximately 1×10¹⁵ cm⁻³.

The electrical characteristics of the structure concerning the relationship between a drain current and a gate voltage are shown in FIG. 12.

In FIG. 12, the voltage between the source and the drain was set to approximately 0.5 V.

Moreover, the electrical characteristics of the structure concerning the relationship between a drain current and the drain voltage are shown in FIG. 13.

In FIG. 13, the gate voltage was varied within the range of from approximately 0.5 V to approximately 3 V.

As illustrated in FIGS. 12 and 13, the semiconductor device according to the embodiment showed excellent characteristics.

The advantages of the semiconductor device and the method according to the embodiment can be summarized as follows.

First, according to the semiconductor device described above, it is possible to maintain a constant threshold voltage even when low-concentration dopants are used.

This is because a spiral gate electrode can be formed in such a state that a constant width of the linear semiconductor layer is maintained from the center of the spiral body to the outer periphery.

In addition, since the sidewall portions of the linear semiconductor layer that forms the channel region are formed of a round surface rather than an angular surface, it is possible to realize a structure that is not sensitive to electric fields.

In addition, unlike the SGT, the channel width can be increased without needing to increase the diameter, and it is thus possible to increase the ON current. Therefore, the area of the semiconductor device on a wafer is relatively small. That is, the area efficiency is improved.

In the semiconductor device according to the embodiment, compared with the SGT, since the linear semiconductor layer forms a channel has a spiral form, the rate of increase in the ON current per a unit wafer area is greater than the rate of increase in the ON current of the SGT.

Up until now, in order to maintain a constant threshold voltage even when the thickness of a semiconductor layer and the channel length are varied, the SGT had a complex design.

For this reason, in order to obtain an efficiently high ON current per a unit wafer area while maintaining good transistor characteristics, it is desirable to have a structure having a large channel width having a spiral form, which is a roll of film like the SFET.

In addition, a high ON current can be realized in a vertical MOS transistor.

As a result, it is possible to provide a transistor structure which is suitable for a memory cell that requires a high ON current, such as PRAM (phase-change memory).

Furthermore, when the semiconductor device of the embodiment is manufactured with a thickness equivalent to the gate height of a conventional planar type transistor, it is possible to a substitute it for the planar type transistor.

In addition, since the channel region is surrounded by the same gate that extends from the center of the spiral body to the peripheral side, it is possible to suppress short channel effects like the FinFET and the SGT. Therefore, it is possible to manufacture a transistor having an extremely short channel length by introducing impurities at the crystal growth step.

Moreover, since the calculation of the PN junction is carried out in a step manner, the transistor design is simple.

Furthermore, compared with the planar type transistor which is manufactured by ion implantation, since the dopants are introduced in the crystal growth step, it is easy to clearly separate the channel region from the drain region or the source region.

For this reason, it is easy to manufacture a transistor having an extremely short channel length.

In addition, the gate of the semiconductor device according to the embodiment can control the channels in the sidewalls on both sides of the linear semiconductor layer at the same time.

That is, it is possible to suppress short channel effects.

In view of the above, since the height of a single-gate vertical transistor can be suppressed to the same height as the gate of the planar type transistor, it is possible to design and manufacture a next-generation, mass-production transistor having an extremely short channel length, which can be a substitute for the planar type transistor.

Moreover, it is possible to realize a structure similar to the SOI-CMOS capable of providing advantages such as parasitic capacitance reduction, latch-up free, junction leakage reduction, or short channel effect suppression without using an SOI substrate and with a low cost.

Furthermore, it is possible to realize three-dimensional integration of transistors.

In addition, since the SOI substrate is not used, it is possible to resolve the self-heating problem, which results from the large difference in the thermal conductivity between the buried oxide film and the silicon layer.

Therefore, it is possible to effectively radiate the heat generated in the semiconductor device in a manner similar to a general substrate.

Moreover, it is possible to provide a structure which can be employed in a floating-body transistor that is used in memory cells of a capacitor-less DRAM.

That is, it is possible to perfectly separate the channel region of the transistor from the semiconductor substrate region, and thanks to the long channel width, it is possible to store a large amount of impact-ionized holes.

Besides, when the above-described structure is employed in the memory cells of a DRAM, it is possible to reduce the junction leakage current and to decrease the number of refreshes per unit time.

In addition, when a plurality of gates are provided in a direction perpendicular to the crystal plane of the semiconductor substrate, capacitors are formed in the source layers between the respective gates.

With this structure, it is possible to implement a multi-valued DRAM in which a plurality of gates is connected to one drain.

Furthermore, when transistors are manufactured in succession in a direction perpendicular to the crystal plane of the semiconductor substrate, it is possible to realize a higher degree of integration, that is, three-dimensional integration.

Specifically, when NMOS and PMOS are manufactured in succession in a direction perpendicular to the crystal plane of the substrate, it is possible to decrease the area of an inverter circuit.

As a first modified example, the semiconductor device of the invention can be applied to an integrated circuit such as a power device, a PRAM (phase-change memory), or a DRAM, which requires a large ON current.

As a second modified example, the semiconductor device of the invention can be applied to a very-high-speed integrated circuit such as a supercomputer or a CPU that operates at a frequency of approximately 10 GHz to approximately 100 GHz.

As a third modified example, the semiconductor device of the invention can be applied to an SOI integrated circuit, such as an integrated circuit for vehicle engine control or an integrated circuit for space satellite, which has excellent radiation characteristics equivalent to the bulk substrate and is capable of coping with severe conditions.

As a fourth modified example, the semiconductor device of the invention can be appropriately applied to a low-cost SOI transistor that does not use the SOI wafer, an integrated circuit that utilizes the exclusive assets of a partial depletion type or a perfect depletion type SOI transistor, and a floating-body transistor that is used in the memory cells of a capacitor-less DRAM.

As a fifth modified example of the semiconductor device of the invention can be applied to a die area reduction technique using three-dimensional integration in a low-cost application-specific LSI (ASIC), a CPU, or a DSP, of the integration level which is defined by a die area.

While preferred embodiments of the invention have been described and illustrated above, it should be understood that these are exemplary embodiments of the invention and are not to be considered as limiting. Additions, omissions, substitutions, and other modifications can be made without departing from the spirit or scope of the invention. Accordingly, the invention is not to be considered as being limited by the foregoing description, and is only limited by the scope of the appended claims.

What is claimed is:

1. A semiconductor device comprising:
a semiconductor substrate having a substrate surface;
a spiral body constituted by a linear semiconductor layer on which a body region including a channel region, a first source/drain region disposed on the body region, and a second source/drain region disposed under the body region or in the semiconductor substrate around the linear semiconductor layer are formed, the linear semiconductor layer being formed on the substrate surface substantially in a spiral form viewed from the substrate surface in a plan view, formed substantially in a protrudent form in a cross-sectional view, and having a pair of sidewall portions;
a gate insulating film formed on at least the pair of sidewall portions constituting the linear semiconductor layer; and
a gate electrode that is adjacent to the pair of sidewall portions via the gate insulating film, wherein
the gate insulating film is disposed between the body region and the gate electrode.

2. The semiconductor device according to claim 1, wherein
a thickness of the linear semiconductor layer, a width of the linear semiconductor layer, and a thickness of the gate insulating film are constant over the spiral body from a peripheral spiral to a central spiral.

3. The semiconductor device according to claim 1, further comprising:
an interlayer insulating film formed on the semiconductor substrate, covering the spiral body, the gate insulating film, and the gate electrode;
a lead-out electrode used for source/drain;
a first contact plug that is connected with the first source/drain region and provided to the interlayer insulating film;
a second contact plug that is connected with the second source/drain region and provided to the interlayer insulating film; and
a gate contact plug that is connected with the gate electrode and provided to the interlayer insulating film, wherein
an end at a peripheral side of the gate electrode is directly connected with the gate contact plug, the first source/drain region is directly connected with the first contact plug, and the second source/drain region is directly connected with the second contact plug via the lead-out electrode.

4. The semiconductor device according to claim 1, wherein
the second contact plug is disposed at a position symmetric to the gate contact plug with respect to a spiral center of the spiral body and the first contact plug is disposed above the spiral center.

5. The semiconductor device according to claim 1, wherein
the pair of sidewall portions constituting the linear semiconductor layer is formed a round surface.

6. A method for manufacturing a semiconductor device, comprising:
providing a semiconductor substrate having a substrate surface;
sequentially forming a first semiconductor film that becomes a second source/drain region, a second semiconductor film that becomes a body region including a channel region, and a third semiconductor film that becomes a first source/drain region, on the semiconductor substrate;
patterning the third semiconductor film, the second semiconductor film, and a part of the first semiconductor film so as to form a linear semiconductor layer that is formed substantially in a protrudent form in a cross-sectional view and that has a pair of sidewall portions, so that the linear semiconductor layer is formed substantially in a spiral form viewed from the substrate surface in a plan view, and so that a spiral body constituted by the linear semiconductor layer is formed;
forming a gate insulating film on at least the pair of sidewall portions of the linear semiconductor layer; and
forming a gate electrode that is opposed to the pair of sidewall portions via the gate insulating film.

7. A method for manufacturing a semiconductor device, comprising:
providing a semiconductor substrate having a substrate surface;
patterning the substrate surface so as to form a linear semiconductor layer that is formed substantially in a protrudent form in a cross-sectional view and that has a pair of sidewall portions, so that the linear semiconductor layer is formed substantially in a spiral form viewed from the substrate surface in a plan view;
sequentially introducing impurities into the semiconductor substrate around the linear semiconductor layer and into the linear semiconductor layer so as to form a second source/drain region in the semiconductor substrate around the linear semiconductor layer and so as to form a body region including a channel region and a first source/drain region on the linear semiconductor layer;
forming a gate insulating film so as to cover the linear semiconductor layer; and forming a gate electrode that is opposed to the pair of sidewall portions via the gate insulating film.
